(19) United States
(12) Patent Application Publication
(10) Pub. No.: US 2011/0089400 A1
(43) Pub. Date: Apr. 21, 2011

(54) NANOWIRE WRAP GATE DEVICES

(75) Inventors: Jonas Ohlsson, Malmo (SE); Lars Samuelson, Malmo (SE); Erik Lind, Lund (SE)

(73) Assignee: QuNano AB

(21) Appl. No.: 12/937,871

(22) PCT Filed: Apr. 15, 2009
(86) PCT No.: PCT/SE09/50388

§ 371 Date: Dec. 23, 2010

(30) Foreign Application Priority Data
Apr. 15, 2008 (SE) 0800853-4

(51) Int. Cl. H01L 33/06; B82Y 99/00; B82Y 20/00

(52) U.S. Cl. 257/13; 257/E33.053; 977/762; 977/950; 977/938

(57) ABSTRACT

The present invention provides a semiconductor device comprising at least a first semiconductor nanowire (105) having a first lengthwise region (121) of a first conductivity type, a second lengthwise region (122) of a second conductivity type, and at least a first wrap gate electrode (111) arranged at the first region (121) of the nanowire (105) in order to vary the charge carrier concentration in the first lengthwise region (121) when a voltage is applied to the first wrap gate electrode (111). Preferably a second wrap gate electrode (112) is arranged at the second lengthwise region (122). Thereby tuneable artificial junctions (114) can be accomplished without substantial doping of the nanowire (105).

### TECHNICAL FIELD OF THE INVENTION

The present invention relates to nanowire-based semiconductor devices in general and to nanowire-based semiconductor devices that requires tailored properties with regards to band gap, charge carrier type and concentration, ferromagnetic properties, etc. in particular.

### BACKGROUND OF THE INVENTION

Semiconductor devices have, until recently, been based on planar technology, which imposes constraint in terms of miniaturization and choices of suitable materials, as described further below. The development of nanotechnology and, in particular, the emerging ability to produce nanowires has opened up new possibilities for designing semiconductor devices having improved properties and making novel devices which were not possible with planar technology. Such semiconductor devices can benefit from certain nanowire specific properties, 2D, 1D, or 0D quantum confinement, flexibility in axial material variation due to less lattice matching restrictions, antenna properties, ballistic transport, wave guiding properties etc.

However, in order to manufacture semiconductor devices, such as field effect transistors, light emitting diodes, semiconductor lasers, and sensors, from nanowires, the ability to form doped regions in the nanowires is crucial. This is appreciated when considering the basic pn junction, a structure which is a critical part of several semiconductor devices, where a built-in voltage is obtained by forming p-doped and n-doped regions adjacent to each other. In nanowire-based semiconductor devices, pn junctions along the length of a nanowire are provided by forming lengthwise segment of different composition and/or doping. This kind of tailoring of the bandgap along the nanowire can for example also be used to reduce both the source-to-gate and gate-to-drain access resistance of a nanowire-based field effect transistor by using lengthwise segments of different bandgap and/or doping level. Commonly the bandgap is altered by using heterostructures comprising lengthwise segments of different semiconductor materials having different bad gap. In addition, the doping level and type of dopant can be varied along the length during, or after, growth of the nanowire. During growth dopants can be introduced in gas phase and after growth dopants can be incorporated into the nanowire by diffusion or the charge carrier concentration can be influenced by so called modulation doping from surrounding layers.

In U.S. Pat. No. 5,362,972, a wrap gate field effect transistor is disclosed. The wrap gate field effect transistor comprises a nanowire of which a portion is surrounded, or wrapped, by a gate. The nanowire acts as a current channel of the transistor and an electrical field generated by the gate is used for transistor action, i.e. to control the flow of charge carriers along the current channel. From the international application WO 2008/034850 it is appreciated that by doping of the nanowire n-channel, p-channel, enhancement or depletion types of transistors can be formed. In the international application WO 2006/135336, heterostructure segments are further introduced in the nanowire of a wrap gate field effect transistor in order to improve properties such as current control, threshold voltage control and current on/off ratio.

The doping of nanowires is challenging due to several factors. For example, physical incorporation of dopants into a crystalline nanowire may be inhibited and the charge carrier concentration obtained from a certain dopant concentration may be lower than expected from doping of corresponding bulk semiconductor materials. For nanowires grown from catalytic particles, using e.g. the so-called VLS (vapor-liquid-solid) mechanism, the solubility and diffusion of the dopant in the catalytic particle will also influence the dopant incorporation. One related effect, with similar long term consequences for nanowires in general is the out-diffusion of dopants in the nanowire to surface sites. This effect is enhanced by the high surface to volume ratio of the nanowire. Surface depletion effects, decreasing the volume of the carrier reservoir, will also be increased due to the high surface to volume ratio of the nanowire.

### SUMMARY OF THE INVENTION

In view of the foregoing, it is an object of the present invention to provide an improvement of semiconductor devices comprising nanowires with regards to properties related to doping of the nanowires. This is achieved by the semiconductor device and the method as defined in the independent claims.

In a first aspect of the invention a semiconductor device comprises at least a first semiconductor nanowire is provided. The nanowire has a first lengthwise region of a first conductivity type, a second lengthwise region of a second conductivity type, and at least a first wrap gate electrode arranged at said first region. Said wrap gate electrode is adapted to vary the charge carrier concentration in at least a first portion of the nanowire associated with the first lengthwise region when a voltage is applied to the first wrap gate electrode.

The second lengthwise region may be arranged in sequence with the first lengthwise region along the length of the nanowire or in a second nanowire that is electrically connected to the first nanowire. Additional wrap gates can be arranged at the second lengthwise region or other regions in order to vary the charge carrier concentration along the length of the nanowire.

The first nanowire of the semiconductor device may comprise a core and at least a first shell layer forming a radial heterostructure, which may be used to produce light.

In one embodiment of the invention the semiconductor device is adapted to work as a thermoelectric element.

In a second aspect of the invention a semiconductor device comprising a nanowire that comprises a ferromagnetic material is provided in order for the semiconductor device to work as e.g. a memory device. This is attained by applying a voltage to a wrap gate electrode arranged at a region of the nanowire in order to change the charge carrier concentration such that the ferromagnetic properties of the ferromagnetic material changes.

Thanks to the invention it is possible to replace conventional doping or avoid substantial doping of semiconductor devices and nanowires based semiconductor devices in particular with local gating and inversion. By way of example this enables the formation of an improved pn junction without space charges in the depletion region as in conventional devices and tunable semiconductor devices, such as a wavelength tunable LEDs (Light emitting Diodes).

Embodiments of the invention are defined in the dependent claims. Other objects, advantages and novel features of the invention will become apparent from the following detailed description of the invention when considered in conjunction with the accompanying drawings and claims.

### BRIEF DESCRIPTION OF THE DRAWINGS

Preferred embodiments of the invention will now be described with reference to the accompanying drawings, wherein:

FIGS. 1a-b are schematic illustrations of a nanowire having a wrap gate electrode for variation of the conductivity of the nanowire according to the invention;

FIGS. 2a-b are schematic illustrations of a nanowire having a double wrap gate for formation of an artificial pn junction according to the invention;

FIGS. 3a-i are schematic illustrations showing the effect of the activation of the wrap gate electrodes in some embodiments of the present invention

FIGS. 4a-c are schematic diagrams of conversion of a depleted nanowire to a nanowire comprising an artificial pn junction according to the invention;

FIGS. 5a-b are schematic illustrations of nanowires comprising a plurality of quantum wells according to the present invention;

FIG. 6 is a schematic illustration of a nanowire comprising a radial heterostructure according to the present invention and a PL-diagram from excitation of such a structure; and

FIG. 7a-b are schematic illustrations of a thermoelectric element according to the present invention.

### DETAILED DESCRIPTION OF EMBODIMENTS

The embodiments of the present invention are based on nanostructures including so-called nanowires. For the purpose of this application, nanowires are to be interpreted as having nanometre dimensions in their width and diameter and typically having an elongated shape that provides a one-dimensional nature. Such structures are commonly also referred to as nanowhiskers, nanorods, nanotubes, one-dimensional nanoelements, etc. The basic process of nanowire formation on substrates by particle assisted growth or the so-called VLS (vapour-liquid-solid) mechanism described in U.S. Pat. No. 7,335,908, as well as different types of Chemical Beam Epitaxy and Vapour Phase Epitaxy methods, are well known. However, the present invention is limited to neither such nanowires nor the VLS process. Other suitable methods for growing nanowires are known in the art and is for example shown in international application No. WO 2007/104781. From this it follows that nanowires may be grown without the use of a particle as a catalyst.

Thus selectively grown nanowires and nanostructures, etched structures, other nanowires, and structures fabricated from nanowires are also included.

Nanowires are not necessarily homogeneous along the length thereof. The nanometer dimensions enable not only growth on substrates that are not lattice matched to the nanowire material, but also heterostructures can be provided in the nanowire. The heterostructure(s) consists of a segment of a semiconductor material of different constitution than the adjacent part or parts of the nanowire. The material of the heterostructure segment(s) may be of different composition and/or doping. The heterojunction can either be abrupt or graded.

The present invention is based on the use of a wrap gate electrode to control the charge carrier concentration of at least a portion of a nanowire that is used as transport channel in a semiconductor device in order to modulate the properties of the nanowire.

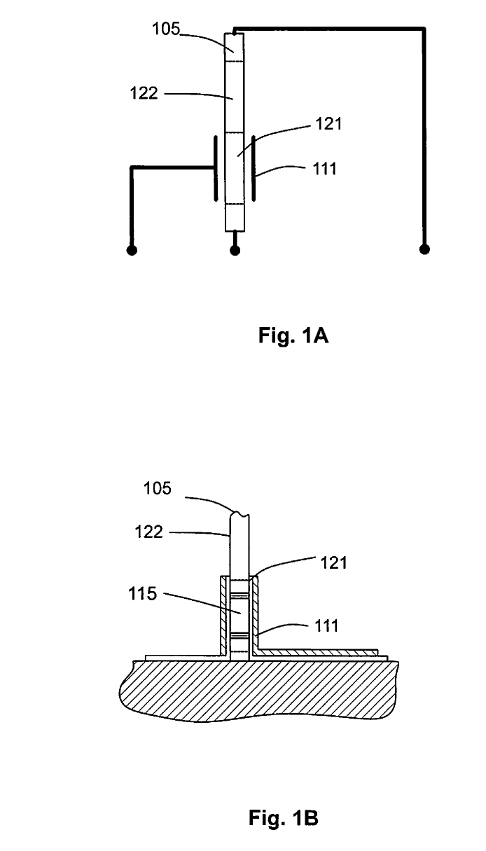

Referring to FIG. 1a, a semiconductor device according to the present invention comprises at least a first semiconductor nanowire 105 forming a transport channel of the semiconductor device, a first lengthwise region 121, a second lengthwise region 122 of a second conductivity type, and at least a first wrap gate electrode 111 arranged at the first lengthwise region 121 of the first nanowire 105 in order to vary the charge carrier concentration in at least a portion of the nanowire associated with the first lengthwise region 121 when a voltage is applied to the first wrap gate electrode 111. The first wrap gate electrode 111 encloses at least a portion of the nanowire 105 with a dielectric material (not shown) in-between.

The effect of this gating is dependent on the voltage applied and the specific design of the semiconductor device, and the first gate electrode 111 and the nanowire 105 in particular, but for example it may cause a change of the charge carrier concentration in the complete first lengthwise region. The change of charge carrier concentration may be made to such an extent that the charge carrier type of a portion of the nanowire changes. This enables creation of different “artificial” devices, such as artificial pn-junctions. The change of charge carrier concentration can also be used to change ferromagnetic properties of the nanowire. This general description of the invention is detailed in the following.

Charge carrier types are commonly referred to as being either p-type or n-type. For the purpose of this application the charge carrier type can also be intrinsic, i.e. i.-type. The p-type material has holes as majority charge carriers, and the n-type material has electrons as majority charge carriers, while the intrinsic-type material is a material without significant majority charge carrier concentration. Hence, the intrinsic-type material may have either electrons or holes as charge carriers although at such a low concentration that the conductivity is due to other properties of the material than these charge carriers.

As mentioned above the nanowire 105 may be homogenous with respect to composition and doping or the nanowire may have been subjected to band gap engineering e.g. by forming heterostructures in along the nanowire. FIG. 1b schematically illustrates a semiconductor device according to one embodiment of the present invention comprising a first non-homogenous nanowire 105 grown in an orthogonal direction from a substrate 104. A first wrap gate electrode 111 extends from the substrate along a portion of the nanowire and encloses a first lengthwise region 121 of the nanowire 105 with a dielectric material in-between 104. The nanowire 105 forms a transport channel, which is electrically connected by a top contact in one end portion of the nanowire 105 and the substrate 104 in the other end of the nanowire 105. The first nanowire 105 comprises at least one quantum well 115, which may be in the form of a quantum dot enclosed by the first wrap gate electrode 111 and one wide bandgap barrier segment on each side of the quantum dot within the first lengthwise region 121.

The first lengthwise region 121 and the second lengthwise region 122 can be of the same or different conductivity type and moreover the conductivity properties can be changed by applying a voltage to one or more wrap gate electrodes. For example, in one embodiment of the present invention, a semiconductor device comprises at least a first nanowire 105 that is homogenously n-doped with a second lengthwise region 122 arranged in sequence with a first lengthwise region 121 along the length of the nanowire 121. A first wrap gate electrode 111 is arranged at the first lengthwise region 121 of the first nanowire 105 to vary the charge carrier concentration so that the first region 121, when a pre-determined voltage is applied to the first wrap gate electrode 111, becomes a p-type region. Accordingly a pn junction is actively formed.

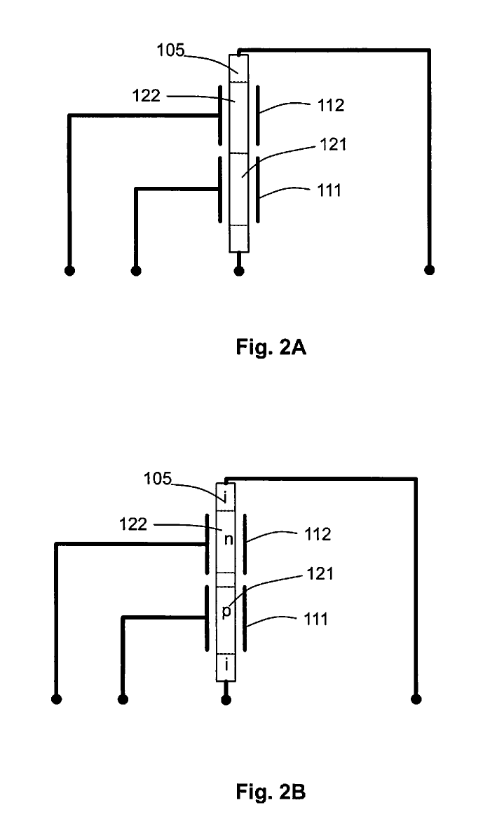

The charge carrier concentration can varied in a plurality of lengthwise regions by arranging a plurality of wrap gate electrodes at the lengthwise regions. Referring to FIG. 2a, a semiconductor device according to one embodiment of the present invention comprises at least a first nanowire 105. The first nanowire 105 has a first wrap gate electrode 111 arranged at a first lengthwise region 121 of the first nanowire 105 and a second wrap gate electrode 112 arranged at a second lengthwise region 122 of the first nanowire 105. Each wrap gate electrode is adapted to vary the charge carrier concentration of the corresponding region 121, 122 of said first nanowire 105 when voltages are applied to the wrap gate electrodes 111, 112. FIG. 2b schematically illustrates such a double-gated nanowire 105 with the wrap gate electrodes activated such that the charge carrier concentrations of the first and second lengthwise regions are changed from originally intrinsic to p-type in the first lengthwise region 121 and n-type in the second lengthwise region 122, thereby forming a pn- or pin junction 114 at the interface 116 between the first lengthwise region 121 and the second lengthwise region 122. By changing the voltages applied, the properties of the pn-junction, such as the properties defined by the width and the position of a depletion region between the p-type region and the n-type region or the width of the p-type and n-type regions, can be varied. As appreciated by one skilled in the art, the either one of the regions 121,122 can be made p-type or n-type and artificial pn-junctions can be formed also from originally n-type or p-type nanowires.

Thus, the variation of the charge carrier concentration of one or more of the first and second regions 121, 122 may be used to form a junction 114 at the interface 116 between lengthwise regions. This junction is either not actually present in the first nanowire 105 before activation of the wrap gate electrodes 121, 122 or a junction between regions of different conductivity type that already is present in the passive state may be moved along the length of the nanowire. This kind of junction is hereinafter referred to as an artificial junction or in the particular case with adjacent regions of p-type and n-type an artificial pn junction. While the invention has been illustrated by examples of embodiments having one or two wrap gate structures per nanowire, it is of course conceivable to have three or more wrap gate structures per nanowire. A plurality of wrap gate electrodes may be arranged at different positions along a nanowire to tailor the charge carrier concentration and/or type along the length of the nanowire.

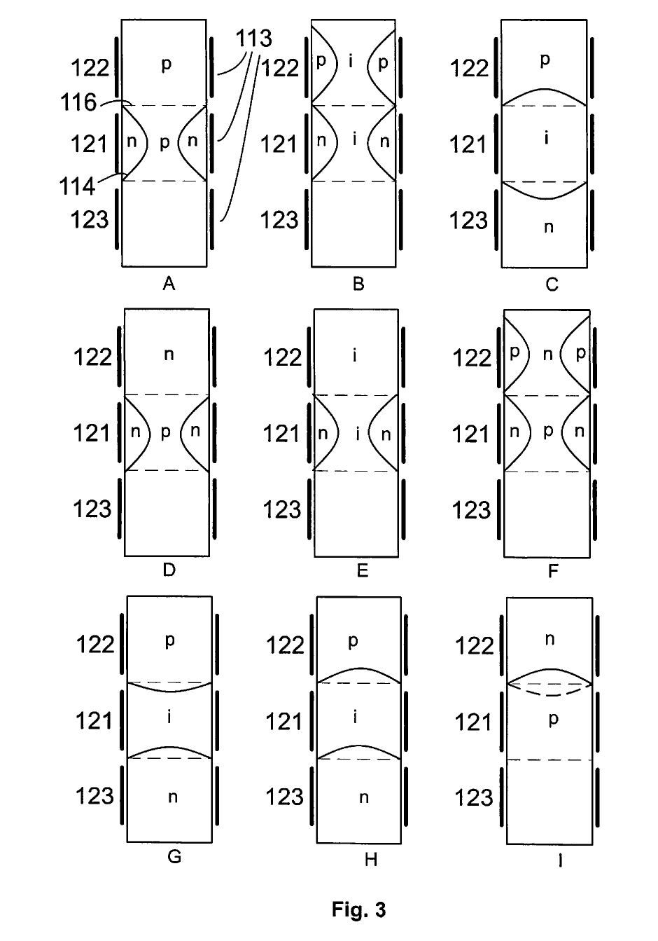

It should be noted that, when the voltage is applied to the first wrap gate electrode 111 that surrounds the first lengthwise region 121, a portion 101 of the nanowire 105 associated with the first lengthwise region 121 changes charge carrier concentration. Analogously, when the voltage is applied to a second or a third wrap gate electrode 111 that surrounds a second lengthwise region 121 and a third lengthwise region 113, respectively, portions 102,103 of the nanowire 105 changes charge carrier concentration. The magnitude of the voltage applied determines the extension of said portion and if the conductivity type is changed. FIGS. 3a-i schematically illustrates embodiments of the present invention with different wrap gate electrode and conductivity type configuration. Although the embodiments are illustrated at an active state when the applied voltage is relatively low and the portions that have changed conductivity type only extend partly into the nanowire or the adjacent regions it should be understood that at a higher voltage level said portions will have larger extension, i.e. the nanowire will change conductivity type over the whole width and over a complete region at a pre-determined voltage level. Only at a certain voltage level a lengthwise junction is formed. A brief description of each of the FIGS. 3a-i are given in the following. In FIG. 3a the first and second lengthwise regions 121,122 are of p-type, and when applying a voltage (potential) to the first wrap gate electrode 111, which is arranged at the said first region 121, at least a portion of the said first region is transferred to n-type. Thus a pn-junction is eventually formed between the said first and second regions 121,122. In FIG. 3b a first and a second region 121,122 are gated by a first and a second wrap gate electrode 111,112, respectively. The nanowire is at least in said regions intrinsic and by applying voltages to the wrap gate electrodes 111,112 at least a portion of the first region becomes n-type and at least a portion of the second region becomes p-type, thereby eventually forming an artificial pn-junction between the first and second regions. The nanowire in FIG. 3c comprises a n-type region 123 and a p-type region with an intrinsic region in-between. By applying voltage to one or more of the wrap gate electrodes, one wrap gate electrode surrounding each region, the interfaces between the intrinsic region 121 and the adjacent regions 122,123 can be moved. In FIG. 3d the nanowire comprises a p-type material in the first region 121 and a n-type material in the second region 122. By operating the device in accordance with FIG. 3a the pn-junction between the first and second regions can be erased. FIG. 3e is the same as FIG. 3a although having intrinsic regions 121,122. In FIG. 3e the first region 121 is p-type and the second region 122 is n-type, but by applying voltages to wrap gate electrodes arranged at each region 121,122 the charge carrier type can be changed, i.e. the pn junction becomes a np junction. FIGS. 3f-g are analogous to FIG. 3c, although with different voltages applied to the wrap gate electrodes or a different configuration of wrap gate electrodes active. FIG. 3i schematically illustrates how an interface between a p-type region and a n-type region can be moved.

The activation of one or a plurality of wrap gates gives the possibility to locally force the band gap in one direction or the other. By having two adjacent wrap gate electrodes forcing the band gap in different directions an artificial pn junction may be accomplished. This makes it is possible to replace conventional doping of nanowires. By way of example this enables the formation of an improved pn junction without space charges in the depletion region as in conventional devices.

As mentioned, the nanowires of the present invention may be e.g. undoped (intrinsic) or only p- or n-doped, which simplifies the manufacturing of nanowire semiconductor devices. The nanowires can be homogenous with respect to doping, however not limited to this. This opens up new possibilities, such as the possibility to use thinner nanowires, which have a true one dimensional behaviour.

The present invention allows the construction of a semiconductor device comprising inhomogeneous induction of regions where transport is carried by electrons and/or holes along a nanowire, where, for instance, one half of the nanowire will be electron-conducting and the other half be hole-conducting, thus effectively providing a tunable artificial pn junction along the length of the nanowire. One advantage of the present invention is that, in principle, undoped nanowires, for which carriers are provided from the gated regions, are used. This enables semiconductor devices, such as rectifiers and light-emitting diodes, which are intimately based on the unique opportunities offered by nanowires. Although single pn junctions have been described above, other kinds of combination of regions behaving as n- and p-regions will be possible, e.g. a gate-induced n-p-n bipolar transistor configuration.

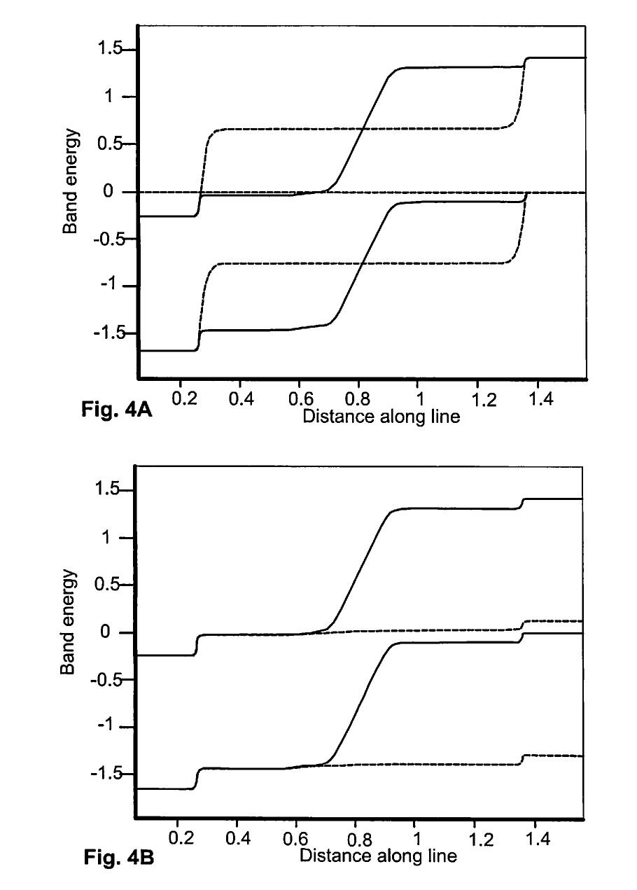

FIG. 4a schematically illustrates local conversion of an otherwise depleted nominally undoped (60 nm diameter) GaAs nanowire 105 according to FIG. 2b, wherein a first region 121 closest to a (p-type) substrate 104 is converted to p-type conductivity, and a second region 122, closest to a n-type termination of the nanowire is converted to n-type conductivity when voltages are applied to the wrap gate electrodes 111,112. These wrap gate electrodes 111,112 can be part of one electrical circuit having a common voltage source in-between, whereby the interface between the converted regions can be moved. For zero-potential on the gates the nanowire 105 is depleted and for +/−3 V on the two gates 111, 112 an n- and p-doped behaviour is resembled. With an applied bias between substrate and the n-type termination, this will operate as an artificial pn junction, by way of example for use as a nano-LED. In one embodiment of the present invention the semiconductor device is functional as such an LED having at least two wrap gate electrodes allowing an recombination region of the LED to be moved along the length of the nanowire, e.g. to obtain a wave-length tunable LED having a graded composition along the length of the nanowire. The graded composition may comprise segments of different composition along the length of the nanowire. Varying dimension, i.e. diameter, is along the length of the nanowire can be used to alone or in combination with varying composition in order to accomplish the tunable LED. FIG. 4b schematically illustrates the behaviour with the applied bias and FIG. 4c illustrates the spatial distribution of electrons and holes at 0V bias and at 1.3V bias.

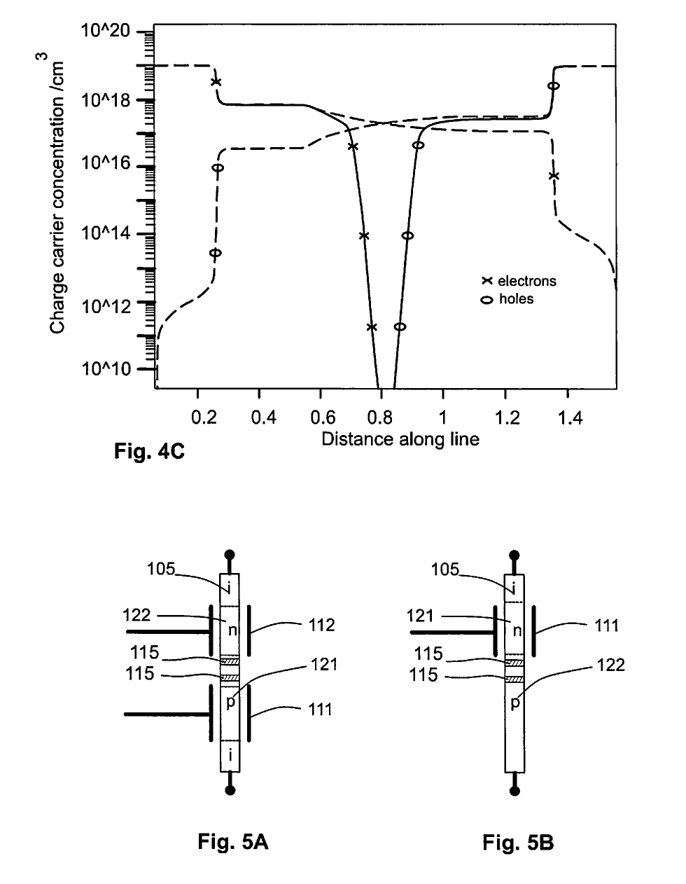

Referring to FIGS. 5a-b, one embodiment of a semiconductor device according to the present invention comprises a first nanowire 105 having a sequence of quantum wells 115 distributed along the length thereof. One or more wrap gate electrodes are arranged at different positions along the length of the nanowire which allows tuning of recombination region to produce light to any of the quantum wells in order to generate light having a predetermined wavelength determined by the composition of the quantum well. In such way switching between discrete wavelengths in a nanowire LED device is conceivable. The wavelength of light emitted from a plurality of nanowires may also be combined to have a broader spectrum. FIG. 5a illustrates a nanowire 105 having two quantum wells of different composition in a position in-between the first and the second wrap gate electrode. By varying the voltages applied to the first and the second wrap gate electrodes 111,112 the extension of the extensions of the portions of the nanowire 105 that have changed charge carrier type from intrinsic to either p-type or n-type can be varied. Thereby the recombination region can be moved to either of the quantum wells. FIG. 5b illustrates another embodiment comprising only a first gate 111 arranged at a first lengthwise region 121 having intrinsic conductivity type in the passive state. In a second lengthwise region 122 the nanowire is of p-type. The recombination region can be moved between two quantum wells of different composition in-between the first and the second regions 121,122.

A mentioned above, the doping of nanowires is challenging. In particular doping of nitride-based III-V semiconductors, for example Mg-doping of GaN, is challenging. The performance of semiconductor devices made of this kind of materials, such as nanowire LEDs, can be improved by using wrap gates to increase the concentration of holes at the recombination region.

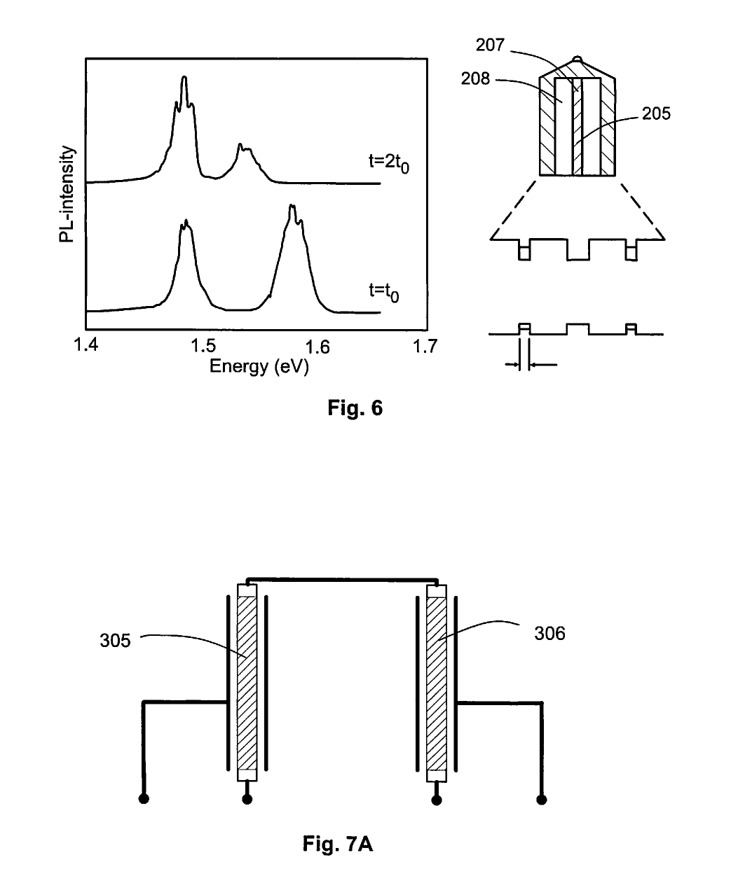

Referring to FIG. 6, one embodiment of a semiconductor device according to the present invention comprises at least a first nanowire 205 comprising a nanowire core 207 and at least a first shell layer 208 epitaxially arranged on the core 207 and at least partly surrounding the nanowire core 207, providing a radial heterostructure. At least a first wrap gate electrode 211 is arranged at a first region 221 of the nanowire 205.

In one embodiment of the present invention both the core and one or more quantum wells defined in the first shell layer surrounding the core are conducting, with the carrier concentration in the shell layer being controlled by a first wrap-gate.

In one implementation of this embodiment both the core and the shell layer are adapted to be electron-conducting by activation of the wrap gate electrode. In another implementation of this embodiment the core is adapted to be n-conducting and the shell to be p-conducting by activation of the wrap gate electrode. In yet another implementation of this embodiment the charge carrier type is tunable.

One embodiment of a semiconductor device according to the present invention comprises a nanowire having a GaAs core and an AlGaAs shell layer. This core-shell structure allows an opportunity to form spatially indirect excitons, i.e. with electrons and holes separated radially. Studies of PL from excitons recombining in the core and in the shell layer of the GaAs/AlGaAs core-shell structure are shown in FIG. 4.

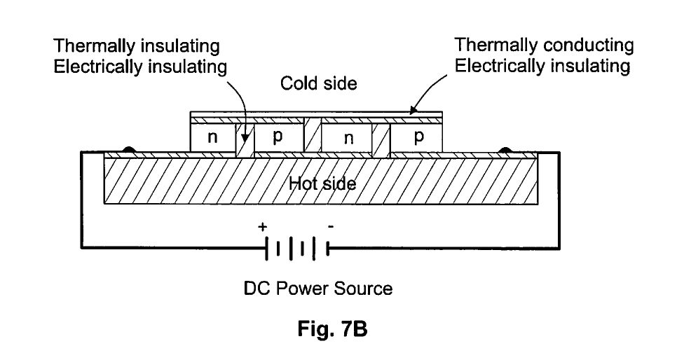

Referring to FIGS. 7a-b, in one embodiment of the present invention the semiconductor device is a thermoelectric element. Wrap gate controlled nanowires 305 makes it possible to use the thermoelements of the present invention in room-temperature thermoelectrics. In general nanowire based technology is considered to be an extremely promising candidate for thermoelectric materials with an energy-conversion efficiency that exceeds traditional cooling and power conversion technologies. One challenge in the field is however the need for both p- and n-type nanowires with equally good performance characteristics to form a thermocouple. N-type devices are usually considered due to the substantially higher mobility for the electrons than for the holes in a typical III/V material. In this embodiment wrap-gate induced carrier conduction is used to define p- and n-type nanowires 305, 306 from otherwise identical nanowires, and tune these such that their performance matches, thus optimizing the performance of the resulting thermoelectric element, such as e.g. a thermocouple or a Peltier element. In one implementation of this embodiment an entire wafer with a checker-board pattern of n- and p-regions are operated to provide thermoelectric effects for heating/cooling.

In another embodiment of the present invention, wherein the semiconductor device is functional as a thermoelectric element, the semiconductor device comprises a radial heterostructure as described above, i.e. a nanowire with a n-type core 307 and a p-type shell layer 308, and at least a first wrap gate electrode 311 surrounding a first region 321 of the nanowire 305 together forming a single-nanowire Peltier element. Whereas an array of a very large number of such nano-Peltier elements could be used for cooling or power generation, a single such element might also represent an extremely effective nano-spot cooler.

One embodiment of the present invention is related to spintronics. In this embodiment wrap-gate-induced carrier-modulation is used for formation and manipulation of ferromagnetic properties of dilutely doped magnetic semiconductors. It is known that free carriers, i.e. free holes, are mediating and inducing the spin-coupling between the magnetic impurities, which in most cases are Mn-impurities with concentrations up to the %-level. Until now, this carrier-mediated spin-coupling leading to ferromagnetic behavior has been extremely difficult to control since the hole-concentration is intimately correlated with the Mn-doping concentration. By arranging one or more wrap gates around nanowires comprising said magnetic semiconductors in a manner described above the present invention it is possible to separately tune the free-carrier concentration using the wrap-gate-induced carrier-modulation.

In one implementation of this embodiment a semiconductor device according to the present invention comprises dense arrays of Mn-doped III-V nanowires, for which an external gate is used to switch the ferromagnetism on and off. This device could be used for magnetic storage. By arranging the nanowires, for example in row and columns, single nanowires are easily addressed. The anisotropy determined by the one-dimensional nature of the nanowires and the two-dimensional array arrangement improves the performance at higher temperatures as compared to conventional storage mediums. Analogously to the gating of nanowires in order to create artificial junctions above and to provide tunable LEDs a plurality of regions, the ferromagnetic properties of multiple regions of one nanowire can be controlled by a plurality of wrap gates arranged along the length of the nanowire. The basic structure for the wrap-gate-induced carrier-modulation for formation and manipulation of ferromagnetic properties is best illustrated by FIG. 1a and FIG. 2a. The charge carrier concentration of the nanowire is locally controlled, not in order to change charge carrier type, but such that the ferromagnetic properties are changed.

Nanowires in semiconductor devices according to the present invention may have a smaller diameter than used in the prior art. The diameter of nanowires in prior art semiconductor devices is typically more than 30 nm, often in the range of 30-50 nm. The present invention allow the use of nanowires having a diameter less than 30 nm, preferably less than 20 nm, and more preferably in the range of 10-20 nm. This is possible since modulation of the charge carrier concentration and/or type of essentially undoped nanowires is used. The present invention is however not limited to homogeneous nanowires, nanowires having a graded or varying composition along the length thereof may be used. Furthermore, radial heterostructures may be utilized, as explained above.

The present invention makes it is possible to manipulate the carrier concentration over large ranges, including carrier inversion, and to do so independently for different segments along nanowires. This approach offers a complete tuning of the Fermi-energy in ideal one dimensional nanowires.

Based on experiences in the creation of ultra-short gate-lengths (about 50 nm), it is possible to stack such wrap-gates vertically. This will enable control of the transport channel of a nanowire along the length thereof via single quantum dots or single electron turn-stile designs.

While the invention has been described for single nanowires it is to be understood that a very large number (few to millions of) nanowires can be collectively gated in identical fashions.

While the invention has been described in connection with what is presently considered to be the most practical and preferred embodiments, it is to be understood that the invention is not intended to be limited to the disclosed embodiments, on the contrary, it is intended to cover various modifications and equivalent arrangements within the scope of the appended claims.

1. A semiconductor device comprising at least a first semiconductor nanowire, wherein the device comprises a first lengthwise region of a first conductivity type, a second lengthwise region of a second conductivity type, and at least a first wrap gate electrode arranged at the first region of the device in order to vary the charge carrier concentration in at least a first portion of the nanowire device associated with the first lengthwise region when a voltage is applied to the first wrap gate electrode, wherein at least the first lengthwise region is arranged in said first nanowire.

2. The semiconductor device according to claim 1, wherein the second lengthwise region is arranged in sequence with the first lengthwise region along the length of the nanowire.

3. The semiconductor device according to claim 1, wherein the second lengthwise region is arranged in a second nanowire being in electrical contact with the first nanowire.

4. The semiconductor device according to claim 1, wherein a second wrap gate electrode is arranged at the second lengthwise region to vary the charge carrier concentration in at least a portion associated with the second lengthwise region when a voltage is applied to the second wrap gate electrode.

5. The semiconductor device according to claim 1, wherein the first lengthwise region and the second lengthwise region are of the same conductivity type.

6. The semiconductor device according to claim 5, wherein at least the first lengthwise region and the second lengthwise region are homogenous with respect to composition and/or doping.

7. The semiconductor device according to claim 5, wherein the first and the second lengthwise regions comprise at least two heterostructure segments of different composition.

8. The semiconductor device according to claim 1, comprising an artificial lengthwise junction at an interface between the first lengthwise region and the second lengthwise region, with different conductivity type on each side of the junction and with the portion on one side thereof, the junction being formed when the voltage is applied.

9. The semiconductor device according to claim 8, wherein the artificial lengthwise junction is a pn junction.

10. The semiconductor device according to claim 1, wherein the first lengthwise region and the second lengthwise region are of different conductivity type.

11. The semiconductor device according to claim 10, wherein an interface between the first lengthwise region and the second lengthwise region, with the portion on one side thereof, comprises a lengthwise junction with different conductivity type on each side of the junction and the first wrap gate electrode is adapted to move the lengthwise junction (when the voltage is applied.

12. The semiconductor device according to claim 1, wherein the first nanowire comprises a third lengthwise region, the first lengthwise region being placed between the second and third lengthwise regions, and wherein one or more wrap gate electrodes are adapted to control the width and position of a depletion region between a p-type region and a n-type region.

13. The semiconductor device according to claim 4, wherein the nanowire comprises an artificial junction formed by the first region having the first wrap gate electrode and the second region having the second wrap gate electrode, being adapted to vary the charge carrier concentration so that either of the first and second regions is a p-type region, and the other is a n-type region.

14. The semiconductor device according to claim 1, wherein said regions and one or more wrap gate electrodes provides an artificial pn or pin junction for the production of light, the active region being adapted to be moved between heterostructure segments of different composition and/or dimension to produce light having different wavelength.

15. The semiconductor device according to claim 1, wherein said regions and one or more wrap gate electrodes provides an artificial pn junction for the production of light, the active region being adapted to be moved along a nanowire segment of a graded composition to produce light having different wavelength.

16. The semiconductor device according to claim 1, wherein the nanowire comprises a core and at least a first shell layer forming a radial heterostructure, and the first wrap gate electrode is adapted to be used for varying the charge carrier concentration in a radial direction of the first lengthwise region of said first nanowire when a voltage is applied to the first wrap gate electrode.

17. The semiconductor device according to claim 16, wherein the radial heterostructure is adapted to comprise an active region to produce light when the voltage is applied.

18. The semiconductor device according to claim 1, wherein at least the first lengthwise region of the first nanowire comprises a magnetic semiconductor material having ferromagnetic properties that can be varied by the variation of the charge carrier concentration of the first lengthwise region.

19. The semiconductor device according to claim 18, wherein the first wrap gate electrode is arranged at the first region of the first nanowire to switch the ferromagnetism in the first region on and off.

20. The semiconductor device according to claim 1, wherein said nanowires are epitaxially arranged on a substrate, and the nanowires are protruding from the substrate.

21. The semiconductor device according to claim 1, wherein the first nanowire comprises a sequence of quantum wells distributed along the length thereof and one or more wrap gate electrodes are arranged at different positions along the length of the nanowire to provide tuning of an active region to produce light to any of the quantum wells.

22. A method of modulating the properties of a first nanowire using at least a first wrap gate electrode arranged at a first region of the first nanowire wherein the method comprises a step of varying at least one of a charge carrier concentration or type or the ferromagnetic properties of the first region of said first nanowire when a voltage is applied to the first wrap gate electrode.

23. The method according to claim 22, wherein the step of varying the charge carrier concentration and/or type is adapted to provide an artificial pn or junction when the voltage is applied to the first wrap gate electrode.
